(19) United States
(12) Patent Application Publication
(10) Pub. No.: US 2008/0061306 A1
(43) Pub. Date: Mar. 13, 2008

(54) Semiconductor light emitting device

(75) Inventors: Kuo An Chiu, New Territories Hong Kong (CN); Yan Huang, Hong Kong (HK); Hung-Shen Chu, New Territories (HK)

Correspondence Address: BUCHANAN, INGERSOLL & ROONEY PC, POST OFFICE BOX 1404, ALEXANDRIA, VA, 22313-1404, US

(73) Assignee: Hong Kong Applied Science and Technology Research Institute Company Limited, New Territories Hong Kong (CN)

(21) Appl. No.: 11/518,912

(22) Filed: Sep. 12, 2006

(51) Int. Cl. H01L 33/00

(52) U.S. Cl. 257/94

(57) ABSTRACT

A semiconductor light emitting device includes a multi-layer stack of materials including a layer of p-doped material, a layer of n-doped material, and a light generating region therebetween; a first thermal conduction path between the light generating region and the exterior of the device; and a second thermal conduction path having a higher thermal conductivity than that of the first thermal conduction path. The second thermal conduction path is for providing enhanced thermal dissipation from the light generating region to the exterior.

### FIELD OF THE INVENTION

The present invention relates to thermal dissipative light emitting diodes. More particularly, the invention relates to a thermally-conductive structure for dissipation of heat from light emitting diodes.

### BACKGROUND OF THE INVENTION

Typically, a light emitting diode (LED) is formed from multiple layers of materials having a layer of p-doped material or p-type semiconductor layer (“p-layer”), a layer of n-doped material or an n-type semiconductor layer (“n-layer”), and a light generating region or p-n junction. When powered, the p-n junction emits lights.

Heat dissipation from the LEDs to the exterior environment is important since LEDs generally exhibit a substantial decrease in light output when the temperature of the LED junction increases. For example, an increase of 75 degrees C.° at the junction temperature may cause the level of luminous flux to be reduced to one-half of its room temperature value. This phenomenon limits the amount of output from conventional LEDs.

It is an object of the present invention to provide a semiconductor light emitting device with improved heat dissipation performance.

### SUMMARY OF THE INVENTION

According to an aspect of the present invention, there is provided a semiconductor light emitting device. The device includes a multi-layer stack of materials including a layer of p-doped material, a layer of n-doped material, and a light generating region therebetween; a first thermal conduction path between the light generating region and the exterior of the device; and a second thermal conduction path having a higher thermal conductivity than that of the first thermal conduction path. The second thermal conduction path is for providing enhanced thermal dissipation from the light generating region to the exterior.

According to a second aspect of the present invention, there is provided a semiconductor light emitting device semiconductor light emitting device, including
a multi-layer stack of materials including a layer of p-doped material, a layer of n-doped material, and a light generating region; and
thermally conductive material embedded within the device adjacent the light emitting region and in thermal communication with the exterior of the device for thermal dissipation from the light generating region to the exterior.

Other aspects and advantages of the invention will become apparent from the following detailed description, taken in conjunction with the accompanying drawings, which description illustrates by way of example the principles of the invention.

### BRIEF DESCRIPTION OF THE DRAWINGS

The invention now will be described, by way of example only, and with reference to the accompanying drawings in which:

FIG. 1 shows a cross sectional view illustrating a first embodiment of a semiconductor light emitting device according to the present invention;

FIG. 2 shows a cross sectional view illustrating a second embodiment of a semiconductor light emitting device according to the present invention;

FIG. 3 is shows cross sectional view illustrating a third embodiment of a semiconductor light emitting device according to the present invention; and

FIG. 4 is shows cross sectional view illustrating a fourth embodiment of a semiconductor light emitting device according to the present invention.

### DETAILED DESCRIPTION

The following description refers to exemplary embodiments of a semiconductor light emitting device of the present invention. Reference is made in the description to the accompanying drawings whereby the light emitting diode is illustrated in the exemplary embodiments. Similar components between the drawings are identified by the same reference numerals.

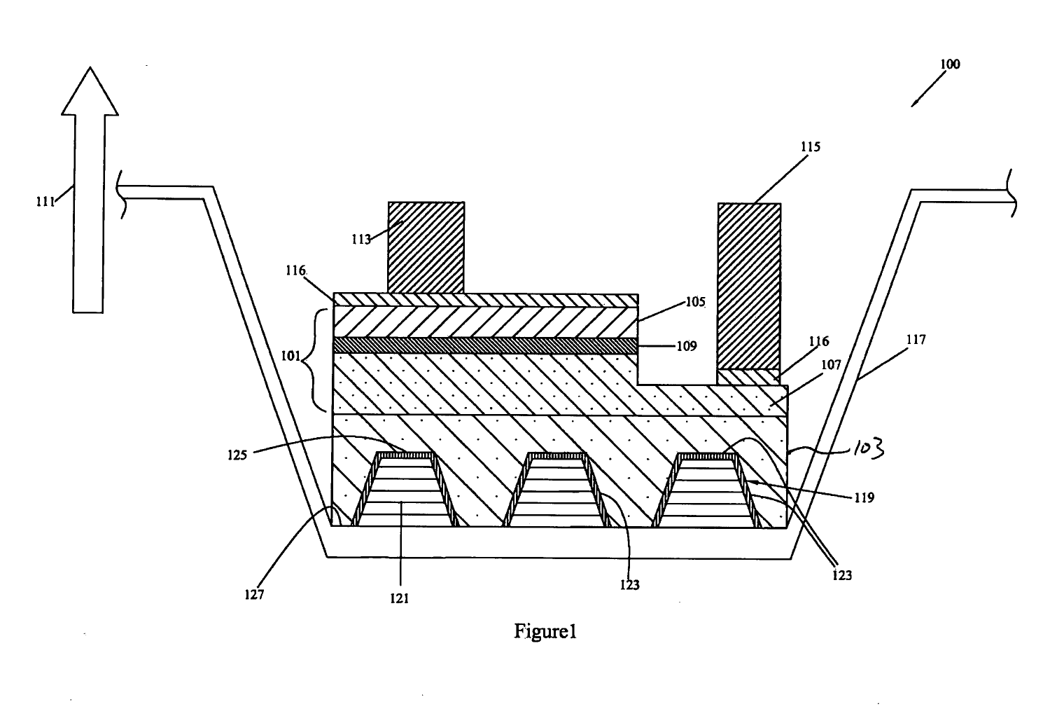

In FIG. 1, an exemplary embodiment of the present invention is shown as a top-emitting semiconductor light emitting device 100. The device 100 includes a multi-layer stack 101 of materials formed on a substrate 103; the multi-layer stack 101 includes a layer of p-doped material or p-type semiconductor layer (“p-layer”) 105, a layer of n-doped material or an n-type semiconductor layer 107 (“n-layer”), and a light generating region or p-n junction 109 as generally understood in the art. When powered, the p-n junction 109 emits lights in all directions; however, a primary amount of light emissions will exit the top-emitting semiconductor light emitting device 100 in a primary light emitting direction indicated by arrow 111, as will be understood in the art. The top-emitting semiconductor light emitting device 100 also has p-electrode 113 and n-electrode 115 for supplying electrical power to the p- and n-layers 105, 107 respectively and may further have a conductive and transparent ITO (Indium Tin Oxide) thin film 116 sandwiched between the electrodes 113, 115 and respective semiconductor layers 105, 107 for improving the electrical connections therebetween as will be understood by an ordinarily skilled person in the art.

In the exemplary embodiment, the top-emitting semiconductor light emitting device 100 is mounted on a packaging 117 which is adjacent a bottom surface 127 of the substrate 103 and which is preferably formed from a metal, metal alloy, or other types of thermally conductive materials. The packaging 117 can be considered the exterior of the top-emitting semiconductor light emitting device 100 in the exemplary embodiment.

Furthermore, a plurality of holes 119 are provided in the substrate 103 by for example etching, with each hole having a depth of about ½-⅚ of the thickness of the substrate 103 and being filled up with thermally conductive materials 121, such as metal, liquid metal, or fluid coolant, such that the thermal conductive materials 121 are in relatively close proximity to the p-n junction 109 and are in contact with the packaging 117 to form thermal communication between the thermal conductive materials 121 and the exterior of the top-emitting semiconductor light emitting device 100. As will be appreciated by those skilled in the art, the holes 119 can be formed by alternative means other than etching.

Thereby, at least two thermal dissipation paths are provided between the p-n junction 109 and the packaging 117. Along a first thermal dissipation path, heat is transmitted from the p-n junction 109 through the n-layer 107 and the full height of the substrate 103 to the packaging 117. Furthermore, heat can be transmitted from the p-n junction 109 to the packaging 117 through a second path defined by the n-layer 107, part of the height of the substrate 103 between the n-layer and the thermal conductive materials 121, and the thermal conductive materials 121. Since the substrate 103 is generally formed from material of relatively low thermal conductivity such as sapphire, SiC and GaN and since from thermal stand point, the thermal conductive materials 121 are closer to the p-n junction 10 in comparison with the packaging 117, the second thermal dissipation path is thermally effectively shorter or has a higher thermal conductivity in comparison with the first thermal dissipation path. Thus, enhanced thermal dissipation is provided from the p-n junction 109 or other parts to the packaging 117 or the exterior of the top-emitting semiconductor light emitting device 100. Those skilled in the art will appreciate that the two thermal paths may be formed integrally within the substrate with the substrate having a heat sink region located integrally therein without departure from the scope of the invention.

An ordinarily skilled person in the art will appreciate that the above-described embodiment can achieve relatively satisfactory thermal dissipation performance at the chip level. Therefore, the production of a relatively more compact LED package may be allowed without the need of relatively complicated or bulky thermal dissipation mechanisms at the packaging level.

Furthermore, as only part of the substrate 103 is etched to form the holes 119, the substrate 103 maintains a suitable strength and therefore allows relatively easy fabrication of the light emitting device 100.

In the exemplary embodiment, the substrate 103 is behind the p-n junction 109 in the primary light emitting direction 111 and can be formed from substantially or partially transparent materials. Optionally, reflective mirror coatings 123 may be provided in each of the holes 119, encapsulating the thermal conductive materials 121, for reducing absorptions of lights by the thermal conductive materials 121 and for reflecting light emitted from the p-n junction 109 so as to enhance the light emission in the primary light emitting direction 111. The relatively close proximity between the top surfaces 125 of the reflective mirror coatings 123 and the p-n junction 109 may also reduce absorptions of lights by the substrate 103 and enhance the light refraction efficiency as compared to a mirror placed at a bottom surface 127 of the substrate 103 in conventional designs and thereby may further enhance the light emissions in the primary light emitting direction 111.

In the exemplary embodiment, the reflective mirror coatings are formed from a reflective material that is preferably also thermal conductive, such as aluminum, gold, silver, chromium, or the like.

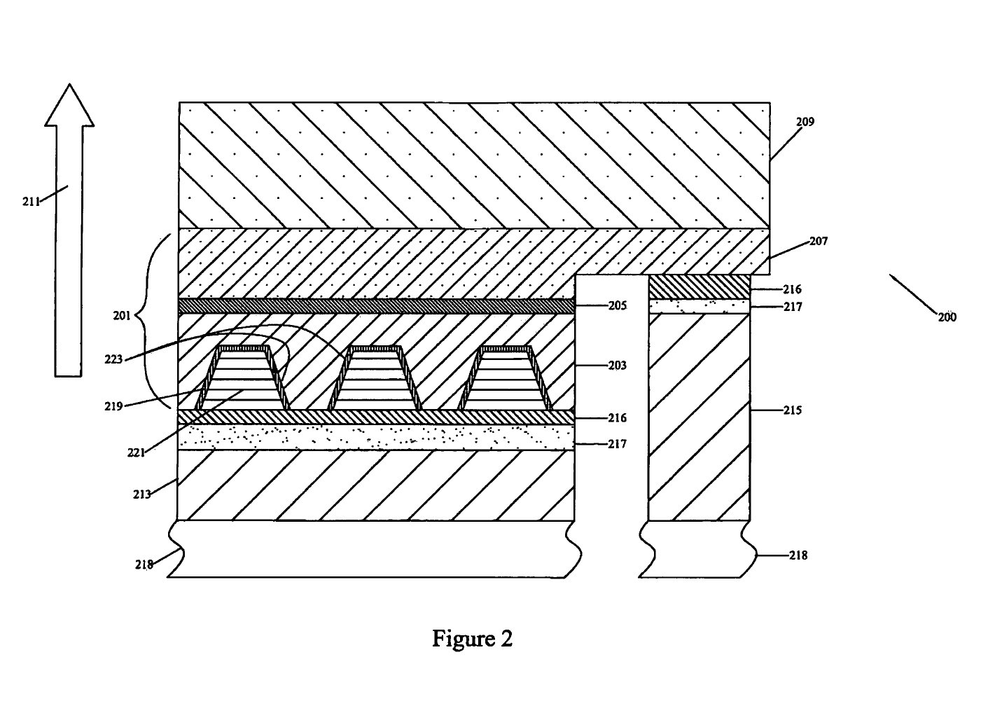

In FIG. 2, a further embodiment of a device 200 according to the present invention is shown as a flip-chip semiconductor light emitting device. The flip-chip light emitting device 200 has a multi-stack 201 including a layer of p-doped material or p-type semiconductor layer 203, a layer of n-doped material or an n-type semiconductor layer 205, and a light generating region or p-n junction 207 as generally understood in the art. When powered, the p-n junction 207 emits lights in all directions, but a primary amount of light emissions will exit the flip-chip semiconductor light emitting device 200 through a substantially transparent substrate 209 attached to a top surface of the n-layer 205 in a primary light emitting direction indicated by arrow 211. The flip-chip semiconductor light emitting device 200 has a p-electrode 213 and an n-electrode 215 for supplying electrical power to the p- and n-layers 203, 207 respectively and can also have a conductive and transparent ITO thin film 216 sandwiched between the electrodes 213, 215 and respective semiconductor layers 203, 207 for improving the electrical connections therebetween as will be understood by an ordinarily skilled person in the art. The flip-chip semiconductor light emitting device 200 can further have a metal mirror layer 217 between the ITO film 216 and the respective electrodes 213, 215 for reflecting light towards the primary light emitting direction 211 as will be understood by an ordinarily skilled person in the art. Furthermore, the electrodes 213, 215 are electrically and thermally connected to a sub-mount 218 for electrical and thermal connection to the exterior of the flip-chip semiconductor light emitting device 200 as again will generally be understood by an ordinarily skilled person in the art.

Similar to the top-emitting semiconductor light emitting device 100 illustrated in FIG. 1, a plurality of holes 219 are created in the p-layer 203, for example, by etching, with each hole having a depth of about ½-⅚ of the thickness of the p-layer 203 and being filled up with thermal conductive materials 221, such as metal, liquid metal, or fluid coolant, such that the thermal conductive materials 221 are in relatively close proximity to the p-n junction 205 and are in contact with the ITO film 216 to form enhanced thermal connection between the thermal conductive materials 221 and the exterior of the top-emitting semiconductor light emitting device 200 through the ITO film, the metal mirror 217 and the electrode 213. Furthermore, reflective mirror coatings 223 may be provided in each of the holes 219, encapsulating the thermal conductive materials 221, for reducing absorption of light by the thermal conductive materials 221, and for reflecting lights emitted from the p-n junction 205 so as to enhance the light emission in the primary light emitting direction 211.

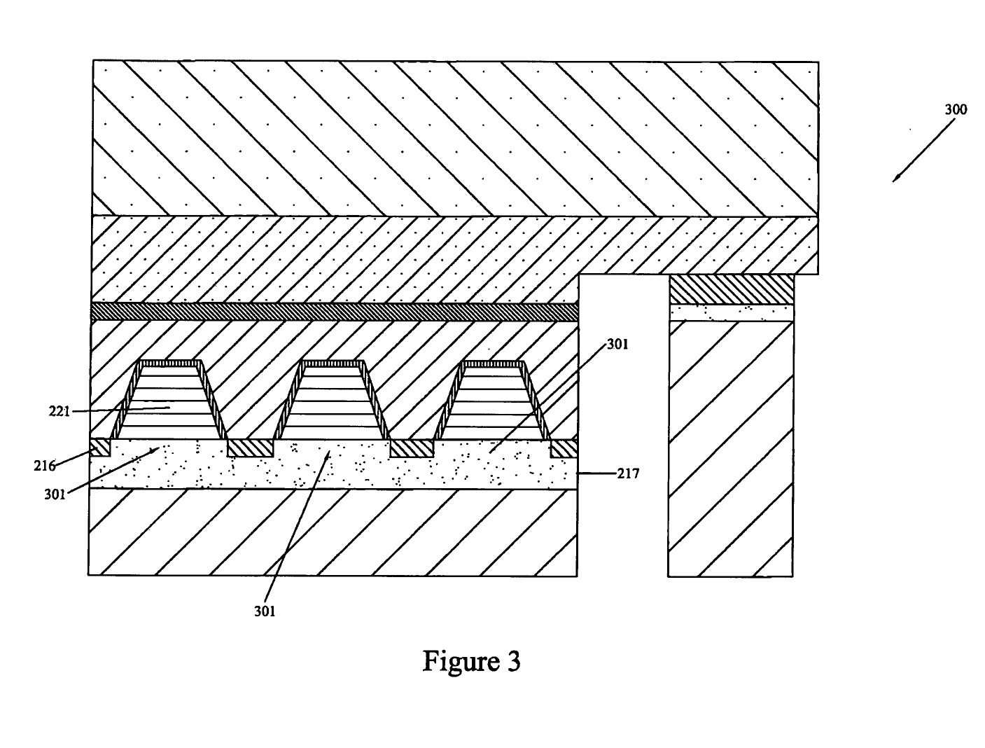

In a second flip-chip semiconductor light emitting device embodiment 300 as shown in FIG. 3, portions 301 of the ITO layer 216 are etched away and filled with the metal mirror 217 such that the thermal conductive materials 221 become in contact with the metal mirror 217 directly to form enhanced thermal connection between the thermal conductive materials 221 and the exterior of the top-emitting semiconductor light emitting device 200 through the metal mirror 217 and the electrode 213.

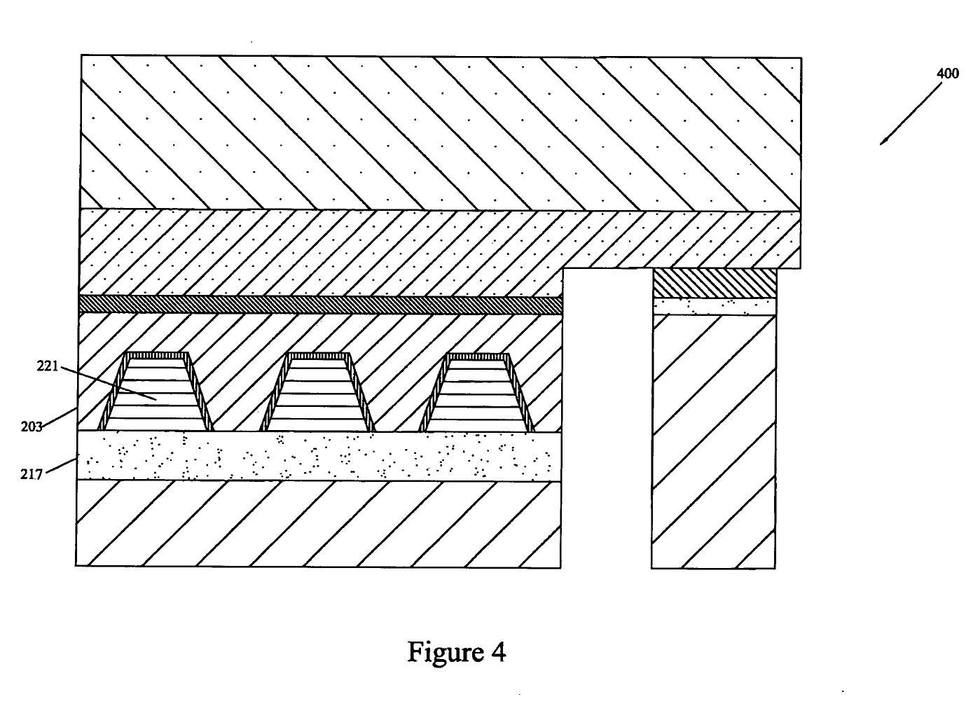

In a further flip-chip semiconductor light emitting device embodiment 400, as shown in FIG. 4, the ITO film is removed such that the p-layer 203 and the embedded thermal conductive materials 221 become in contact with the metal mirror 217 directly to form enhanced thermal connection between the thermal conductive materials 221 and the exterior of the top-emitting semiconductor light emitting device 200 through the metal mirror 217 and the electrode 213.

It will be understood that the invention disclosed and defined herein extends to all alternative combinations of two or more of the individual features mentioned or evident from the text or drawings. All of these different combinations constitute various alternative aspects of the invention. The foregoing describes an embodiment of the present invention and modifications, apparent to those skilled in the art can be made thereto, without departing from the scope of the present invention.

Although the invention is illustrated and described herein as embodied, it is nevertheless not intended to be limited to the details described, as various modifications and structural changes may be made therein without departing from the spirit of the invention, and within the scope and range of equivalents of the claims.

Furthermore, it will be appreciated and understood that the words used in this specification to describe the present invention and its various embodiments are to be understood not only in the sense of their commonly defined meanings, but also to include by special definition in this specification structure, material or acts beyond the scope of the commonly defined meanings. Thus, if an element can be understood in the context of this specification as including more than one meaning, then its use in a claim must be understood as being generic to all possible meanings supported by the specification and by the word itself. The definitions of the words or elements of the following claims are, therefore, defined in this specification to include not only the combination of elements which are literally set forth, but all equivalent structure, material or acts for performing substantially the same function in substantially the same way to obtain substantially the same result, without departing from the scope of the invention.

What is claimed is:

1. A semiconductor light emitting device comprising
a multi-layer stack of materials including a layer of p-doped material, a layer of n-doped material, and a light generating region therebetween;
a first thermal conduction path between the light generating region and the exterior of the device; and
a second thermal conduction path having a higher thermal conductivity than that of the first thermal conduction path, said second thermal conduction path being for providing enhanced thermal dissipation from the light generating region to the exterior.

2. A semiconductor light emitting device, comprising
a multi-layer stack of materials including a layer of p-doped material, a layer of n-doped material, and a light generating region; and
thermally conductive material embedded within the device adjacent the light emitting region and in thermal communication with the exterior of the device for thermal dissipation from the light generating region to the exterior.

3. The device of claim 2, further comprising a substrate on which the multi-layer stack is formed and in which the thermal conductive material is embedded.

4. The device of claim 3, wherein the device is a top-emitting semiconductor light emitting device, and wherein the substrate is mounted on a thermal conductive packaging, with the packaging thermally connected to the thermal conductive material.

5. The device of claim 4, further comprising a plurality of holes formed in the substrate, said plurality of holes being for containing the thermal conductive material.

6. The device of claim 5, wherein the depth of the holes extends about ½ to ⅚ of the thickness of the substrate.

7. The device of claim 2, wherein the thermal conductive material is selected from a group including metal, metal alloy, liquid metal, fluidic coolant or the like.

8. The device of claim 2, having a primary light emitting direction, wherein the thermal conductive material is positioned behind the light generating region in the primary light emitting direction.

9. The device of claim 9, further comprising at least a light reflective mirror coating encapsulating at least a portion of the thermal conductive structure, said coating being for reflecting light so as to enhance light emission in the primary light emitting direction.

10. The device of claim 10, wherein the light reflective mirror coating is formed from a reflective metal.

11. The device of claim 11, wherein the light reflective metal is selected from a group including aluminum, gold, silver, chromium, or the like.

12. The device of claim 2, wherein the device is a flip-chip semiconductor light emitting device having a primary light emitting direction, and wherein the thermal conductive material is embedded within one of the n-layer and p-layer behind the light generating region in the primary light emitting direction.

13. The device of claim 12, further comprising a plurality of holes formed in said one of the n-layer and p-layer, said plurality of holes being for containing the thermal conductive material.

14. The device of claim 13, wherein the depth of the holes extends about ½ to ⅚ of the thickness of said one of the n-layer and p-layer.

15. The device of claim 12, further comprising at least a light reflective mirror coating encapsulating at least a portion of the thermal conductive material, said light reflective mirror coating being for reflecting light so as to enhance light emission in the primary light emission direction.

16. The device of claim 12, further comprising an electrode to which the thermal conductive materials are thermally connected, said electrode being for supplying power to said one of the n-layer and p-layer.

17. The device of claim 16, further comprising a light reflective layer between the electrode and said one of the n-layer and p-layer, wherein the light reflective layer is both thermally and electrically conductive.
